(19) United States
(12) Patent Application Publication
(10) Pub. No.: US 2025/0233109 A1
(43) Pub. Date: Jul. 17, 2025

(54) PACKAGE ARCHITECTURE WITH INTERPOSER

(71) Applicant: Powerchip Semiconductor Manufacturing Corporation, Hsinchu (TW)

(72) Inventors: Chun-Lin Lu, Hsinchu (TW); Shou-Zen Chang, Hsinchu (TW)

(73) Assignee: Powerchip Semiconductor Manufacturing Corporation, Hsinchu (TW)

(21) Appl. No.: 18/590,951

(22) Filed: Feb. 29, 2024

(30) Foreign Application Priority Data
Jan. 12, 2024 (TW) 113101395

(51) Int. Cl. H01L 25/065; H01L 23/00; H01L 23/48; H10B 80/00

(52) U.S. Cl. CPC H01L 25/0652; H01L 23/481; H01L 24/08; H01L 24/16; H10B 80/00; H01L 2224/08225; H01L 2224/16225; H01L 2225/06517; H01L 2225/06541

(57) ABSTRACT

A package architecture with interposer is provided in the present invention, including a package substrate, an interposer bonded on the package substrate, wherein the interposer is comprised of a plurality of vertically-stacked memory dies and a topmost routing layer, and a plurality of chips bonded on the routing layer.

### BACKGROUND OF THE INVENTION

### 1. Field of the Invention

The present invention relates generally to a package architecture with interposer, and more specifically, to a package architecture with interposer comprised of memory dies.

### 2. Description of the Prior Art

Since the development of the integrated circuit (IC), the semiconductor industry has experienced continued rapid growth due to continuous improvements in the integration density of various electronic components (i.e. transistors, diodes, resistors, capacitors, etc.). For the most part, these improvements in integration density have come from repeated reductions in minimum feature size, which allows more components to be integrated into a given area.

These integration improvements are essentially two-dimensional (2D) in nature, in that the area occupied by the integrated components is essentially on the surface of the semiconductor wafer. The increased density and corresponding decrease in area of the integrated circuit has far more surpassed the ability to bond an integrated circuit chip directly onto a substrate, resulting in ordinary chip packaging technology unable to keep up the increase of I/O bump number and the decrease of bump pitch in chips. Accordingly, the 2.5D packaging technology using interposers to redistribute bump contact areas from that of the chip to a larger area of the interposer has emerged in the industry, such as the CoWoS (chip on wafer on substrate) technology provided by TSMC, with interposer functioning as a medium between chips and IC substrate to change bump pitch and trace width. In addition, the presence of interposers may also fulfill three-dimensional (3D) package that includes multiple chiplets, and other packaging technology may be developed therefrom to be incorporated into possible 3D package scheme in the future.

Nevertheless, currently available 2.5D packaging using interposer is substantially a kind of 2D package architecture. Various chips set on the interposer, ex. logic chip and high bandwidth memory (HBM) chip, still use the interposer as a transmission path and are arranged side-by-side on the interposer to achieve horizontal 2D connection rather than 3D connection, which is unable to further reduce the transmission path between chips like those in the 3D chip stacking, and its limited layout space can't adapt to technology development in the future to set larger system-on-a-chip (SoC) and more memory chips. Accordingly those of skilled in the art still need to develop and improve current 2.5D packaging technology using interposer, in hope of further improving its performance.

### SUMMARY OF THE INVENTION

In the light of the aforementioned disadvantage in prior art, the present invention hereby provides a package architecture with interposer, with feature of an interposer comprised of vertically-stacked memory dies, so that the memory chips once set on the interposer may be set directly in the interposer to achieve vertical 3D connection with the system-on-a-chip (SoC) or logic chip on the interposer as well as increase available layout area on the interposer.

The purpose of present invention is to provide a package architecture with interposer, with structure including a package substrate, an interposer on the package substrate, wherein the interposer is comprised of a plurality of vertically-stacked memory dies and a topmost routing layer, and multiple chips on the routing layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a package architecture with interposer in accordance with one embodiment of the present invention; and

FIG. 2 is a schematic cross-sectional view of a package architecture with interposer in accordance with another embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

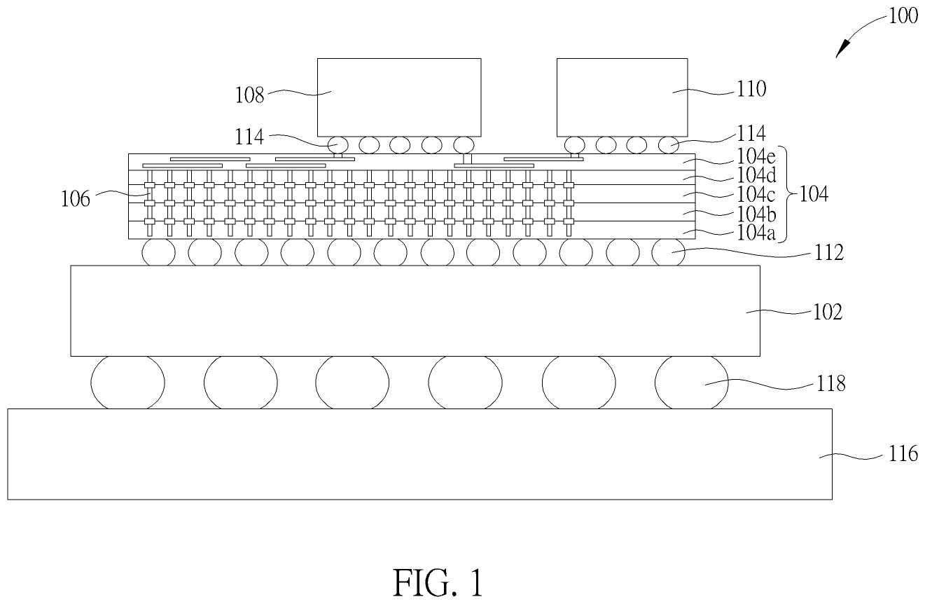

Please refer to FIG. 1, which is a schematic cross-sectional view of a package architecture with interposer in accordance with one embodiment of the present invention. The package architecture 100 of present invention includes a bottommost package substrate 102 (may also be referred as IC substrate or IC carrier), mainly as a carrier to carry ICs and connect the chips set thereon with a printed circuit board (PCB) 116 below through its internal circuit to transmit signal therebetween, so as to function as a buffer interface for the electrical connection and transmission between chips and PCB, with efficacy of protecting circuits, fixing circuits and dissipating residual heat. Classified by their package scheme, the package substrate 102 may be but not limited to BGA (ball grid array) substrate, CSP (chip scale package) substrate or FC (flip chip) substrate. Classified by the material of substrate, the package substrate 102 may be but not limited to BT (bismaleimide triazine) resin substrate, ABF (ajinomoto build-up film) substrate or even MIS (molded interconnect substrate) substrate. Conductive wires formed of copper foils are usually provided in the package substrate 102 to ensure the output of logic gates in chips may match the maximum number of the input of logic gates on the connected PCB through its fan-out scheme. However, please note that in the embodiment of present invention, Chips are not directly connected on the package substrate 102. Instead, an interposer is used as a medium therebetween, which belongs to 2.5D package architecture.

Refer still to FIG. 1. The package architecture 100 of present invention includes an interposer 104, ex. a silicon interposer, set on the aforementioned package substrate 102. In the embodiment, the function of interposer 104 is to fulfill the information exchange between chips and package substrate with different I/O sizes through its fine pitch tracing and routing ability based on 2.5D packaging technology. As shown in figure, the interposer 104 may be electrically connected with the package substrate 102 below through solder bumps 112 (ex. C4 bumps) set on its lower surface. On the other hand, the interposer 104 may be electrically connected with various chips 108, 110 above through micro bumps (u-bumps) 114 set on its upper surface. The interposer 104 may change bump pitch and trace width through internal routing to make chip packaging possible for advanced process, further improving the performance and bandwidth of chips. In addition, the presence of interposer may also fulfill 3D package that encompasses multiple chiplets/dies to increase the integration density between chips.

Please note that, different from the interposer used merely for routing and changing bump pitch in prior art, the interposer 104 of present invention is comprised of a plurality of vertically-stacked memory dies 104a, 104b, 104c, 104d and a topmost routing layer 104e. In the embodiment, the memory dies 104a, 104b, 104c, 104d constituting the interposer 104 may be a whole DRAM wafer, SRAM wafer or other types of memory wafer, while through-silicon vias (TSVs) 106 or hybrid bonding (ex. Cu—Cu bumpless hybrid bonding) may be used to achieve vertical 3D stacking and integration between the memory wafers. The topmost routing layer 104e in the interposer 104 functions as a redistribution layer (RDL) to redistribute the bumps and I/Os of the chips. In other embodiment, the bottom of interposer 104 may also be provided with another routing layer (not shown) to redistribute bottom circuits.

Please refer still to FIG. 1. In the embodiment, various chips 108, 110 may be set on the interposer 104 (only two chips are exemplified in the figure, but not limited thereto). These chips 108, 110 are arranged horizontally on the topmost routing layer 104e of interposer 104. The chips 108, 110 and interposer 104 may achieve electrical connection through the u-bump 114 therebetween and be further electrically and respectively connected with the memory dies 104a, 104b, 104c, 104d in vertical direction. In the embodiment, chips 108, 110 may include system-on-a-chip (SoC), high bandwidth memory (HBM), microelectromechanical systems (MEMS) chip, sensor chip, or various chiplets with different functions like logic chiplet, radio frequency (RF) chiplet, etc., or various integrated passive devices (IPD). These chips 108, 110 may achieve heterogeneous integration in the same package structure through the interposer 104. Lastly, in the embodiment of present invention, the whole package architecture 100 including package substrate 102, interposer 104 and chips 108, 110 may be bonded on a printed circuit board (PCB, ex. cellphone, PC or the PCB in peripheral electronic device) 116 through solder bumps 118 (ex. C4 bumps) after package. The material of PCB 116 may be FR-4. In certain design, the package architecture 100 may not be provided with package substrate 102, instead, is bonded directly on the PCB 116 through the interposer 104.

As far as the present invention is concerned, the advantage of using 3D vertically-stacked memory dies as an interposer is that the memory, ex. HBM or SRAM, once set on the interposer may be optionally set in the interposer, like in a part of the interposer right under the SoC corresponding to the memory. In this way, not only can lots of the layout area be saved for other chips, but true 3D vertical stacking scheme may also be achieved between the SoC and the corresponding HBM, significantly reducing the transmission path between memory and logic chip, fulfilling the bandwidth and performance desired by advanced process and package. Furthermore, in the embodiment of present invention, the integration density of memory cells in the memory dies 104a, 104b, 104c, 104d may be designedly corresponded to the integration density of chips right above. For example, the integration density of memory cells in the part of interposer 104 with SoC set thereon may be designedly larger in order to match larger integration density of the SoC thereon, and the integration density of memory cells in the part of interposer 104 with RF chiplet or IPDs set right above or without any chip/device set thereon may be designedly smaller or be provided with partial dummy cells, in order to match smaller integration density of the circuits right thereon. The advantage of this design is that the I/O bump number and pitch on the surface of interposer 104 may be better matched with the bump number and pitch of the chip connected right thereon, makes it simple and easy for circuit redistribution and routing in interposer 104, which is another advantage of the present invention. Accordingly, the design of interposer and package architecture of the present invention may be suitable in the package field of intermediate and advanced application, like 5G mobile device, automotive electronics, internet of things (IoT), high performance computing (HPC) and artificial intelligence (AI), fulfilling the requirement in the aspect of performance, power consumption, size and overcoming the challenge in package process and cost.

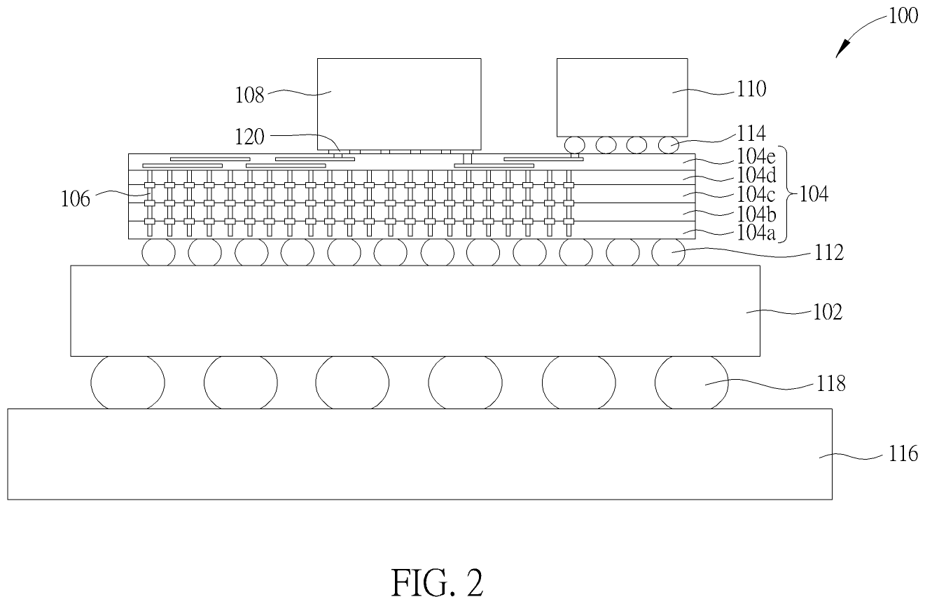

Please refer now to FIG. 2, which is a schematic cross-sectional view of a package architecture with interposer in accordance with another embodiment of the present invention. The package architecture 100 of this embodiment is the same essentially as the embodiment shown in FIG. 1, including similarly a bottommost package substrate 102 and an interposer 104 set on the package substrate 102. The interposer 104 is comprised of a plurality of vertically-stacked memory dies 104a, 104b, 104c, 104d and a topmost routing layer 104e, and a plurality of chips 108, 110 are set on the routing layer 104e. The difference between this embodiment and the aforementioned embodiment lies in that the chips (ex. chip 108) set on the interposer 104 may be electrically connected with the interposer 104 through hybrid bonding (ex. Cu—Cu bumpless hybrid bonding) 120.

In summary of the embodiments above, the present invention utilizes multilayered, vertically-stacked memory dies as an interposer, so that the interposer of present invention may provide 2D communication between a plurality of chips set thereon in horizontal direction, as well as provide 3D communication between the chips and the memory dies in vertical direction, to achieve the purposes of saving layout area and reducing signal transmission path.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package architecture with interposer, comprising:
a package substrate;
an interposer on said package substrate, and said interposer is comprised of a plurality of vertically-stacked memory dies and a topmost routing layer; and
a plurality of chips horizontally arranged on said routing layer, wherein said chips are electrically and respectively connected with said memory dies.

2. The package architecture with interposer of claim 1, wherein said memory dies are provided with multiple memory cells, and an integration density of said memory cells corresponds to an integration density of said chips right above said memory cells.

3. The package architecture with interposer of claim 1, wherein said memory dies are bonded together through through-silicon vias (TSVs) or hybrid bonding.

4. The package architecture with interposer of claim 1, wherein said chips are bonded on said routing layer through micro bumps or hybrid bonding.

5. The package architecture with interposer of claim 1, wherein said interposer is bonded on said package substrate through C4 bump.

6. The package architecture with interposer of claim 1, wherein said chips comprise system-on-a-chip (SoC), high bandwidth memory (HBM), integrated passive device (IPD), logic chiplet, radio frequency (RF) chiplet or microelectromechanical systems (MEMS) chip.

7. The package architecture with interposer of claim 1, further comprising another routing layer in a bottommost layer of said interposer.

8. The package architecture with interposer of claim 1, wherein said memory dies are DRAM dies or SRAM dies.

9. The package architecture with interposer of claim 1, wherein said package substrate is BT (bismaleimide triazine) resin substrate, ABF (ajinomoto build-up film) substrate or MIS (molded interconnect substrate) substrate.
